(19) United States
(12) Patent Application Publication
(10) Pub. No.: US 2013/0286591 A1
(43) Pub. Date: Oct. 31, 2013

(54) Power Electronics Cooling

(71) Applicants: Scott R. Myers, Stuart, FL (US); David Huber, Tequesta, FL (US)

(72) Inventors: Scott R. Myers, Stuart, FL (US); David Huber, Tequesta, FL (US)

(73) Assignee: General Electric Company, Schenectady, NY (US)

(21) Appl. No.: 13/459,979

(22) Filed: Apr. 30, 2012

(51) Int. Cl. H05K 7/20; F25B 9/06

(52) U.S. Cl. 361/700; 62/6; 361/699

(57) ABSTRACT

A system for cooling components of a power generation system. The system may include a working fluid, 100% of which may be sent to a heat exchanger for cooling the components. During cooling, the working fluid may be retained in liquid form. All of the working fluid exiting the heat exchanger may be introduced to an evaporator which may transform the working fluid to a gas for use by an expander or other device to create motive power to run a generator. Upon exiting the expander, the gas may be condensed back to liquid form, 100% of which may be sent back to the heat exchanger to cool the components.

### TECHNICAL FIELD

The subject matter disclosed herein relates generally to power conversion systems, and more particularly to cooling systems for power converters.

### BACKGROUND OF THE INVENTION

In the power generation industry, high speed generators are used to generate electrical power at relatively high frequencies (typically a number of times higher than the grid frequency), and power converters are used to convert the high frequency AC power down to an AC grid frequency of 50 or 60 Hz. This is accomplished by rectifying the high frequency AC signal and then generating a new sinusoidal AC wave of the desired frequency. The creation of the new wave involves the use of integrated gate bipolar transistors (IGBT's), which are switched at a carrier frequency rate, which is an order of magnitude higher than the power converter output frequency. Because of the necessary repeated on and off switching of the IGBT's, they generate a substantial amount of heat which must be dissipated. Without cooling this dissipated heat, the temperatures of solid state junctions in the IGBT's would exceed the maximum values, and the transformers would be permanently damaged. Accordingly, all high frequency power conversion equipment typically applies some type of cooling in order to control these junction temperatures.

One known method of cooling IGBT's is the use of forced-convection air-cooled finned cold plates to which the IGBT's are mounted. In order to dissipate the heat from the cold plate, a cooling fan is directed to circulate cool air over the fins. Another method of cooling IGBT's is through use of a cooling water heat exchange system. According to another method, a relatively small amount of cold, high pressure, liquid refrigerant from an organic rankine cycle system is diverted to the power converter where it is expanded into a plurality of internal openings in the cold plate, with the flashing of the refrigerant reducing the temperature of the cold plate.

An Organic Rankine Cycle (ORC) is similar to the cycle of a conventional steam turbine, except for the fluid that drives the turbine. In place of steam, the ORC employs a high molecular mass organic fluid. Some of the chemicals used in ORC's are Freon, butane, propane, ammonia, as well as many new environmentally friendly refrigerants. The selected working fluids allow system designers to exploit low temperature heat sources to produce electricity in a wide range of power outputs (from a few kW up to 3 MW electric power per unit). For that reason, ORC's find wide use in geothermic heat pump systems. In a typical ORC the organic working fluid is vaporized by application of the heat source in an evaporator (ORC-EVA). The organic fluid vapor expands in a turbine (ORC-TUR) and is then condensed using a flow of water in a condenser (ORC-CON) (alternatively, ambient air can be used for cooling). The condensed fluid is pumped back to the evaporator thus closing the thermodynamic cycle.

A fundamental rankine cycle typically includes a turbo generator, an evaporator/boiler, a condenser, and a liquid pump. In another method to generate electricity from waste heat, single cycle system or two-cycle systems are used in heat recovery applications with waste heat sources of different temperature levels. Single-cycle configurations collect heat from the different waste heat locations in a serial arrangement of heat exchangers with an intermediate heating fluid. In two-cycle configurations, the hot heat source heats a high-boiling point liquid in a top loop, and the cold heat source heats a low-boiling point liquid in a separate bottom loop.

### BRIEF DESCRIPTION OF THE INVENTION

The present disclosure thus describes a method that may comprise the steps of providing a cold plate, mounting at least one transistor on the cold plate in heat exchange relationship therewith, and introducing a flow of liquid refrigerant in the vicinity of the cold plate, thereby cooling the cold plate and the transistor, while maintaining all of the liquid refrigerant in a liquid state.

The present disclosure further describes a power conversion system that may comprise a high frequency generator operatively coupled to an expander, a power converter connected to the high frequency generator, the power converter configured to convert high frequency AC power to lower frequency AC power, the power converter having a plurality of switching mechanisms in heat exchange relationship with a structure on which the plurality of switching mechanisms are mounted, the structure being configured to receive from a condenser a liquid to provide cooling to the switching mechanisms. The power conversion system may further comprise an evaporator configured to receive all the liquid exiting the structure on which the switching mechanisms are mounted, evaporate the liquid to a gas, and introduce the gas to the expander. The condenser may be configured to receive the gas exiting the expander, condense the gas to liquid, and introduce via a pump all of the condensed liquid to the structure on which the switching mechanisms are mounted.

The present disclosure further describes a rankine cycle system that may comprise an evaporator coupled to a heat source and configured to circulate a working fluid in heat exchange relationship with a hot fluid from the heat source so as to heat the working fluid and vaporize the working fluid, an expander coupled to the evaporator and configured to expand the vaporized working fluid from the evaporator, a condenser coupled to the expander and configured to condense the vaporized working fluid from the expander, a pump coupled to the condenser and configured to feed all of the condensed working fluid from the condenser to a power converter, wherein the condensed working fluid acts to cool components of the power system, and a connection that feeds all of the condensed working fluid from the power converter to the evaporator.

These and other features of the present disclosure will become apparent to one of ordinary skill in the art upon review of the following detailed description when taken in conjunction with the drawings and the appended claims.

### BRIEF DESCRIPTION OF THE DRAWINGS

FIG. 1 is a power generation system in accordance with the present disclosure.

FIG. 2 is a schematic illustration of a cooling arrangement for a power converter in accordance with the present disclosure.

### DETAILED DESCRIPTION

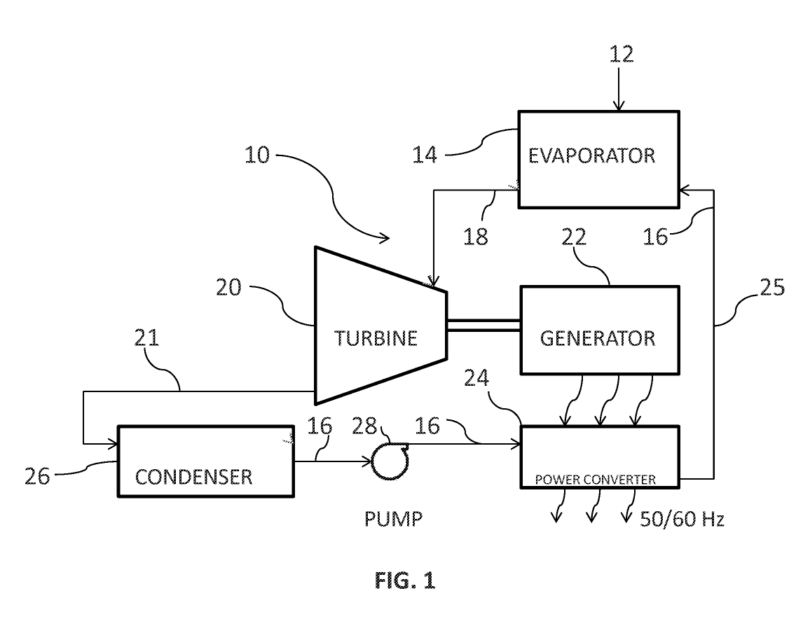

Referring now to FIG. 1, there is disclosed a power generation system, generally 10, of the present disclosure. As shown, the power generation system 10 may make use of an external heat source, 12, which may be waste heat and/or combustion gasses from a gas turbine or other heat source. The heat source 12 may be directed to an evaporator 14, where the heat from the external heat source 12 may be used to evaporate a working fluid such as a liquid 16 that may be fed into the evaporator 14. The working fluid 16 may be a refrigerant, including organic refrigerants known in the art, and may be vaporized in the evaporator 14 into a gas 18. The gas 18 may then be further heated, to super-heat the gas 18, before being passed into an expander, such as a turbine 20, which may cause the turbine 20 to rotate, producing motive power that may be utilized by a load, 22, such as a high frequency generator to which the turbine or expander 20 may be operatively coupled. The expander 20 may, for example, be a radial type expander, axial type expander, impulse type expander, high temperature screw type expander, or positive displacement type expander, such as are known to those of ordinary skill in the art.

The high frequency generator, 22, in turn, may be operatively coupled to a power converter, 24, which may convert the high frequency AC power generated by the high frequency generator 22 to lower frequency AC power, such as 50 or 60 Hz.

The power converter 24 may include switching mechanisms in heat exchange relationship with a structure on which they are mounted, which switching mechanisms may comprise one or more transistors, such as insulated gate bipolar transistors (IGBT's).

The expander 20 may direct the gas 18 leaving the expander 20 via line 21 to a condenser 26, which may condense the gas 18 back to working fluid 16 in the liquid state. This working fluid 16, which is now cooled and in liquid form, may then be directed, such as with a pump 28, to the power converter 24, where it may be used to cool the components, such as the IGBT's, contained therein.

All of the working fluid 16 may be retained in the liquid state during this cooling operation in the power converter 24. In this way, only sensible heat may be added to the working fluid 16; latent heat of vaporization would not be needed. In use, 100% of the working fluid 16 employed in the power generation system 10 may thus be passed through a heat exchanger, such as a cold plate, associated with the power converter 24. In addition to cooling the switching mechanisms, for example, IGBT's, mounted to the cold plate, this heats the working fluid prior to its being pumped to the evaporator 14 via line 25, reducing the heat needed in the system and creating improved system efficiency. Thus, the pump 28 may be used to further enhance system efficiency in that 100% of the pump's power may be used in the cycle to send the working fluid 16 to the heat exchanger associated with the power converter 24, thereby cooling the switching mechanisms, such as IGBT's, and the pump's power is further used to cycle the working fluid 16 to the evaporator 14 via line 25 for evaporation, subsequent contribution to turbine/expander motivation, and ultimately power production. Thus, 100% of the pump's power may be used in the cycle to produce usable electricity.

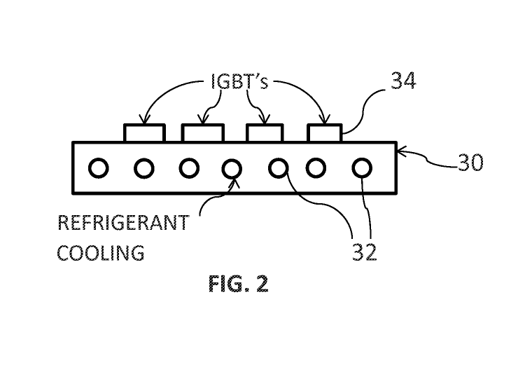

Referring now to FIG. 2, there is illustrated a schematic view of a cold plate of the present disclosure, generally 30. As illustrated the cold plate 30 may have a plurality of internal openings 32 for passing a working fluid such as working fluid 16 therethrough in order to cool the cold plate 30. Mounted to the cold plate may be one or more switching mechanisms 34, such as IGBT's. The pump 28 illustrated in FIG. 1 may pump 100% of the relatively cold, high pressure working fluid 16, such as a liquid refrigerant, from the condenser 26 to the power converter 24, where it may be received by the cold plate internal openings 32, and where it may be retained in the liquid state while cooling the cold plate 30 and mounted switching mechanisms 34. All of the working fluid 16 may then be cycled to the evaporator 14 through the line 25 as previously described, to repeat the cycle. Because 100% of the working fluid 16 may be pumped to the cold plate 30, Rankine Cycle efficiency gains may be realized, in that the IGBT inefficiency in the form of waste heat may be converted into an Organic Rankine Cycle efficiency increase, as the heat from the IGBT's reduces the amount of heat needed from the external heat source 12 to evaporate the working fluid 16. Furthermore, all of the pumped working fluid 16 may be used to produce power in the cycle, avoiding wasted pump power of prior art systems that divert a portion of the pumped fluid for IGBT cooling, which then flashes the working fluid to a gas that must be cycled to the condenser. As no flashing typically occurs in the system of the present disclosure, all of the working fluid 16 may be pumped to the power converter 24 or other element that needs cooling, where it may remain in the liquid state before cycling to the evaporator 12.

The system disclosed herein may be used in connection with an Organic Rankine Cycle-based generator system, which may use an organic working fluid of the type known in the art. Exemplary organic working fluids are described in Saleh, B., et al., Working fluids for low-temperature organic Rankine cycles (2006, Elsevier Ltd.), available online at www.sciencedirect.com, incorporated in its entirety by reference herein. Exemplary organic working fluids include, without limitation, cyclohexane, cyclopentane, thiophene, ketones, aromatics, propane, butane, pentafluoro-propane, pentafluoro-butane, pentafluoro-polyether, or combinations thereof

This written description uses examples to disclose the invention, including the best mode, and also to enable any person of ordinary skill in the art to practice the invention, including making and using any devices or systems and performing any incorporated methods. The steps recited in the accompanying method claims need not be taken in the recited order, where other orders of conducting the steps to achieve the desired result would be readily apparent to those of ordinary skill in the art. The patentable scope of the invention is defined by the claims, and may include other examples that occur to those of ordinary skill in the art. Such other examples are intended to be within the scope of the claims if they have structural elements that do not differ from the literal language of the claims or if they include equivalent structural elements with insubstantial differences from the literal languages of the claims.

What is claimed:

1. A method comprising the steps of:
providing a cold plate;
mounting at least one transistor on the cold plate in heat exchange relationship therewith; and
introducing a liquid refrigerant in the vicinity of said cold plate, thereby cooling said cold plate and said at least one transistor, while maintaining all of said liquid refrigerant in a liquid state.

2. The method of claim 1 further comprising circulating all of said liquid refrigerant from said cold plate to an evaporator, said evaporator evaporating said liquid refrigerant to a gas.

3. The method of claim 2 further comprising introducing said gas into an expander configured to receive a gas medium and convert its energy to motive power.

4. The method of claim 3 wherein said gas exits said expander and is introduced to a condenser where it is condensed to said liquid refrigerant.

5. The method of claim 4 wherein said all of the condensed liquid refrigerant from said expander is circulated to said cold plate.

6. The method of claim 1 wherein said at least one transistor comprises an insulated gate bipolar transistor.

7. The method of claim 1 wherein said liquid refrigerant comprises an organic liquid.

8. A power conversion system comprising:
a high frequency generator operatively coupled to an expander;
a power converter connected to said high frequency generator, said power converter configured to convert high frequency AC power to lower frequency AC power, said power converter having a plurality of switching mechanisms in heat exchange relationship with a structure on which said plurality of switching mechanisms are mounted, said structure being configured to receive from a condenser a liquid to provide cooling to said switching mechanisms;
an evaporator configured to receive all the liquid exiting said structure, evaporate the liquid to a gas, and introduce said gas to said expander; and
said condenser configured to receive said gas exiting said expander, condense said gas to said liquid, and introduce all of said liquid to said structure.

9. The power conversion system of claim 8 wherein said plurality of switching mechanisms comprise transistors.

10. The power conversion system of claim 9 wherein said transistors comprise insulated gate bipolar transistors.

11. The power conversion system of claim 8 wherein said structure comprises a cold plate.

12. The power conversion system of claim 8 wherein said liquid comprises an organic refrigerant.

13. The power conversion system of claim 8 wherein said evaporator is heated by combustion gases.

14. A rankine cycle system comprising:
an evaporator coupled to a heat source and configured to circulate a working fluid in heat exchange relationship with a hot fluid from the heat source so as to heat the working fluid and vaporize the working fluid;
an expander coupled to the evaporator and configured to expand the vaporized working fluid from the evaporator;
a condenser coupled to the expander and configured to condense the vaporized working fluid from the expander;
a pump coupled to the condenser and configured to feed all of the condensed working fluid from the condenser to a power converter, wherein said condensed working fluid acts to cool components of said power system while remaining in a liquid state; and
a connection that feeds all of the condensed working fluid from said power converter to said evaporator.

15. The rankine cycle system of claim 14 wherein the working fluid comprises cyclohexane, cyclopentane, thiophene, ketones, aromatics, propane, butane, pentafluoro-propane, pentafluoro-butane, pentafluoro-polyether, or combinations thereof

16. The rankine cycle system of claim 14 wherein said power converter comprises a plurality of switches mounted to a structure configured to receive said condensed working fluid to cool said switches.

17. The rankine cycle system of claim 16 wherein said switches comprise transistors.

18. The rankine cycle system of claim 17 wherein said transistors comprise insulated gate bipolar transistors.

19. The rankine cycle system of claim 18 wherein said structure comprises a cold plate.

20. The rankine cycle system of claim 14 wherein said system efficiency is improved by utilizing waste heat from said power converter to warm said working fluid prior to passing said working fluid into said evaporator, thereby reducing the amount of heat needed from said heat source to evaporate said working fluid.

21. The rankine cycle system of claim 14 wherein all of the working fluid passing through said pump cycles to said evaporator to produce power in said system.
